(19) United States
(12) Patent Application Publication
(10) Pub. No.: US 2022/0193835 A1
(43) Pub. Date: Jun. 23, 2022

(54) SOLDERING DEVICE

(71) Applicant: HAKKO CORPORATION, Osaka (JP)

(72) Inventors: Yuta Mishima, Osaka (JP); Teruhiko Yamamoto, Osaka (JP); Yoshitomo Teraoka, Osaka (JP)

(21) Appl. No.: 17/690,898

(22) Filed: Mar. 9, 2022

Related U.S. Application Data
(63) Continuation of application No. PCT/JP2020/034200, filed on Sep. 9, 2020.
(60) Provisional application No. 62/898,295, filed on Sep. 10, 2019.

(51) Int. Cl. B23K 37/02; B23K 3/08; B23K 3/02

(52) U.S. Cl. CPC B23K 37/0258; B23K 2101/42; B23K 3/025; B23K 3/08

(57) ABSTRACT

A soldering device includes: a soldering iron; a driver for moving the soldering iron; an input receiver for receiving an input of size information of a workpiece; and a controller for controlling the driver. The controller sets a coordinate of a specific position at a predetermined distance away from a soldering position based on the size information, sets, a speed of a tip at a distant position to a predetermined speed, and sets, an evacuation speed from the soldering position to the specific position to a low speed which is lower than the predetermined speed.

### CROSS-REFERENCE TO RELATED APPLICATION

This is a continuation application of International Application No. PCT/JP2020/034200 filed on Sep. 9, 2020 which claims the benefit of priority from U.S. application No. 62/898,295 filed on Sep. 10, 2019. The entire contents of the earlier applications are incorporated herein by reference.

### TECHNICAL FIELD

The present disclosure relates to a soldering device.

### BACKGROUND

Soldering devices have been widely used for soldering a workpiece, such as an electronic component, to a land of a printed circuit board. Such a soldering device includes a soldering iron, a solder wire feeder for feeding a solder wire, an actuator for moving a soldering tip (hereinafter the “tip”) of the soldering iron to a desired position, and a controller for controlling these elements.

Incidentally, soldering performed by using a soldering device in the related art may cause solder scattering when the soldering tip moves away from a land. The scattered solder may adhere on the printed circuit board between lands or between terminals of electronic components. The solder scattered and adhered between the lands in the aforementioned manner may cause a malfunction or a short circuit.

The solder scattering occurring in the evacuation of the tip is suppressed by setting a speed of the tip evacuating (moving away) from the land to a lower speed. For example, JP-U-S62-015863 discloses, besides am air cylinder for mainly moving the soldering iron, a configuration including an air cylinder and a cam mechanism to slow down the moving speed of a tip during evacuation. Specifically, in this configuration, the cam mechanism is used to move the tip to a position at a predetermined distance away from a land at a low speed, and after the tip reaches the aforesaid position (evacuation position), subsequently move the tip to the next land at a faster speed to perform the next soldering.

JP-A-2019-115918 discloses a configuration to slow down the speed of the tip evacuating from a land than the speed of the tip approaching and abutting the land, by the control of an actuator.

However, the soldering devices in the related art faces difficulty in suppressing the solder scattering during the evacuation of the tip while maximally preventing a tact time from being prolonged in soldering intended for various sizes of workpieces. In other words, in JP-U-S62-015863, the predetermined distance is determined depending on the size of the cam mechanism. It is seen from this perspective that, in the technology disclosed in JP-U-S62-015863, the size of the cam mechanism is determined based on the largest workpiece among workpieces subjected to soldering. Therefore, the technology disclosed in JP-U-S62-015863 has a problem that the tip is required to travel an unnecessarily long predetermined distance at the low speed even when a workpiece having a small size is soldered, resulting in prolonging tact time.

Furthermore, the technology disclosed in JP-A-2019-115918 fails to describe the distance required for the tip to travel from the land at a low speed.

### SUMMARY

The object of the present disclosure is to provide a soldering device which can suppress solder scattering in evacuation of a tip while maximally preventing a tact time from being prolonged.

A soldering device according to one aspect of the present disclosure is a soldering device for joining a workpiece to a land provided on a main surface of a printed circuit board. The soldering device according to this aspect includes: a soldering iron having a tip which is heatable; a driver configured to move the soldering iron, an input receiver configured to receive an input of size information about a size of the workpiece; and a controller configured to control the driver.

The controller sets, based on the size information, a coordinate of a specific position at a predetermined distance from a soldering position where the tip performs soldering. The controller sets a speed of the tip in evacuation which is at a distant position farther away from the soldering position than the specific position to a predetermined speed, and sets an evacuation speed of the tip in evacuation from the soldering position to the specific position to a speed which is slower than the predetermined speed.

### BRIEF DESCRIPTION OF DRAWINGS

FIG. 1 is a perspective view showing a configuration of a soldering device according to an embodiment of the present disclosure.

FIG. 2 is a block diagram showing a configuration of a control system included in the soldering device.

FIG. 3 is a cross-sectional view showing a structure of a through-hole printed circuit board and a land.

FIG. 4 is a plan view showing a planer shape of the land shown in FIG. 3.

FIG. 5 is a cross-sectional view showing a structure of a surface mount printed circuit board and a land.

FIG. 6 is a plan view showing a planer shape of the land shown in FIG. 5.

FIG. 7 is a cross-sectional view explaining a tip evacuation angle.

FIG. 8 shows a relation between a shape of a tip of a first type and a shape offset amount thereof.

FIG. 9 shows a relation between a shape of a tip of a second type and a shape offset amount thereof.

FIG. 10 shows a relation between a shape of a tip of a third type and a shape offset amount thereof.

FIG. 11 is a flowchart showing a way of setting an evacuation position of the tip by the controller.

FIG. 12 is a cross-sectional view showing the evacuation position of the tip.

FIG. 13 is a chart showing a relation between a tip position and a tip evacuation speed.

FIG. 14 is a perspective view showing a structure of a solder wire.

FIG. 15 is a front view showing a tip shape of a soldering iron used in experiments.

FIG. 16 is a plan view showing the tip shape of the soldering iron used in experiments.

FIG. 17 is a graph showing a relation between a tip evacuation speed and the number of solder scatterings when solder type A is used.

FIG. 18 is a graph showing a relation between a tip evacuation speed and the number of solder scatterings when solder type B is used.

FIG. 19 is a cross-sectional view showing an evacuation position of a tip set in a soldering device according to a first modification.

FIG. 20 is a cross-sectional view showing an evacuation position of a tip set in a soldering device according to a second modification.

FIG. 21 is a chart showing a relation between a tip position and a tip evacuation speed set in a soldering device according to a third modification.

FIG. 22 is a chart showing a relation between an elapsed time from a start of tip evacuation and a tip evacuation speed in a soldering device according to a fourth modification.

### DETAILED DESCRIPTION

Hereinafter, an embodiment of the present disclosure will be described with reference to the accompanying drawings. It should be noted here that the embodiment to be described below illustrates one example of the invention and does not delimit the protection scope of the present invention.

### Embodiment

1. Configuration of Soldering Device 1

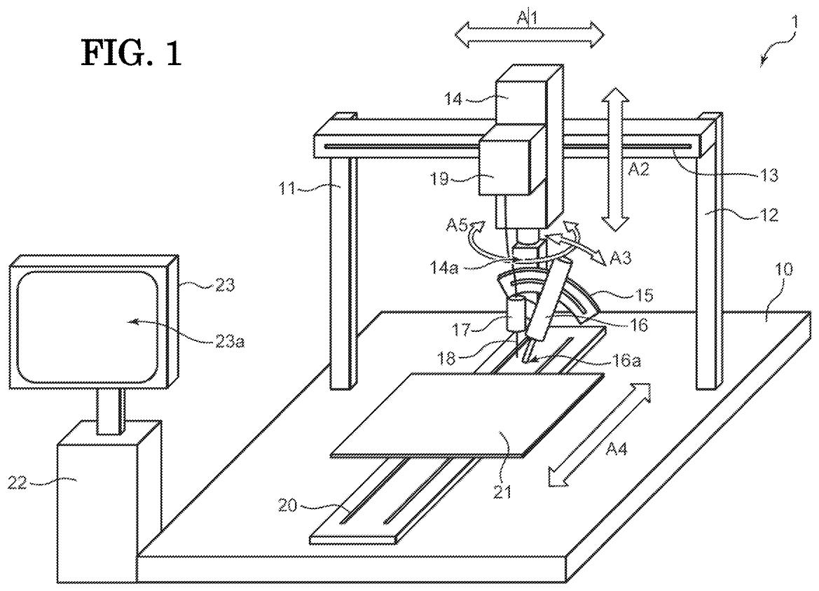

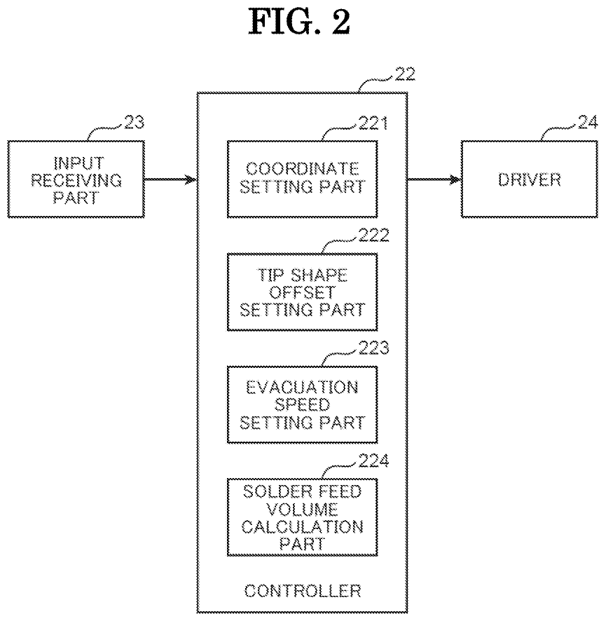

A soldering device 1 according to an embodiment of the present disclosure will be described with reference to FIG. 1 and FIG. 2.

As shown in FIG. 1, the soldering device 1 according to the embodiment includes a base 10 and two frames 11, 12 standing on the base 10. Each of the frames 11, 12 is formed of a long prism-shape, and the frames are spaced away from each other.

The soldering device 1 includes linear actuators 13, 14. The linear actuator 13 bridges upper ends of the frame 11 and the frame 12. The linear actuator 14 is connected to the linear actuator 13. The linear actuator 13 is configured to be movable along an arrow A1. The linear actuator 14 has a head 14a at a distal end thereof. The linear actuator 14 is configured to be movable along an arrow A2.

The soldering device 1 further includes a iron support member 15, a soldering iron 16, and a solder wire feeder 17. The iron support member 15 is, for example, a frame having an arc shape, and is connected to the head 14a of the linear actuator 14. The soldering iron 16 is attached to the iron support member 15.

The posture (attachment angle) of the soldering iron 16 with respect to the iron support member 15 can be changed as shown along arrow A3. The head 14a is rotatable along arrow A5.

The soldering iron 16 has a tip 16a at a distal end thereof. The tip 16a is configured to be heatable through a power supply from an unillustrated power supply part.

The solder wire feeder 17 is configured to send out a solder wire 18 from a distal end thereof to the tip 16a. The solder wire feeder 17 receives the solder wire fed from a solder wire accommodation part 19 fixedly attached to the linear actuator 14.

The soldering device 1 further includes a linear actuator 20 and a board mount table 21. The linear actuator 20 is arranged on the base 10. The linear actuator 20 is configured to allow the board mount table 21 to move thereon along arrow A4. The board mount table 21 is configured such that a printed circuit board is mountable thereon and fixedly attachable thereto.

The soldering device 1 includes a “driver” composed of the linear actuators 13, 14, 20 for moving the soldering iron 16 relative to the printed circuit board.

The soldering device 1 further includes a controller 22 and an input receiving part 23. The controller 22 has a microprocessor. The microprocessor includes a CPU, a RAM, and a ROM. The CPU is composed of, for example, an MPU, and controls each of the linear actuators 13, 14, 20 by executing corresponding firmware.

The input receiving part 23 has a touch panel (input section) 23a. An operator inputs various information via the touch panel 23a. The information input by the operator via the touch panel 23a includes a size of a workpiece, a tip evacuation angle, a shape of the tip 16a, a cross-sectional shape of the solder wire 18, and a feed amount of the solder wire 18. The input information will be described in detail later.

As shown in FIG. 2, the controller 22 receives various information from the input receiving part 23 and sends out a control signal of the driver 24. The controller 22 has a coordinate setting part 221, a tip shape offset setting part 222, an evacuation speed setting part 223, and a solder feed volume calculation part 224. The coordinate setting part 221 sets a coordinate of a position (specific position) at a predetermined distance away from a soldering position. The soldering position is where the tip 16a performs soldering, and the specific position is a position after a workpiece is soldered to a predetermined land. The tip shape offset setting part 222 sets an offset amount upon setting the coordinate of the evacuation position of the tip 16a, depending on the shape of the tip 16a of the soldering iron 16.

The evacuation speed setting part 223 sets a moving speed of the soldering iron 16 when the tip 16a of the soldering iron 16 is evacuating. The solder feed volume calculation part 224 calculates a feed amount of the solder wire 18 to be fed for soldering the workpiece to the land from the information of the solder wire 18 which is input via the input receiving part 23.

A wide variety of setting by the controller 22 will be described later.

2. Shape of Land

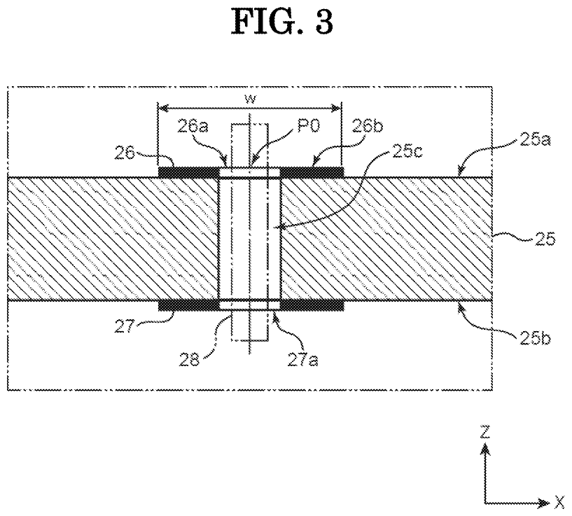

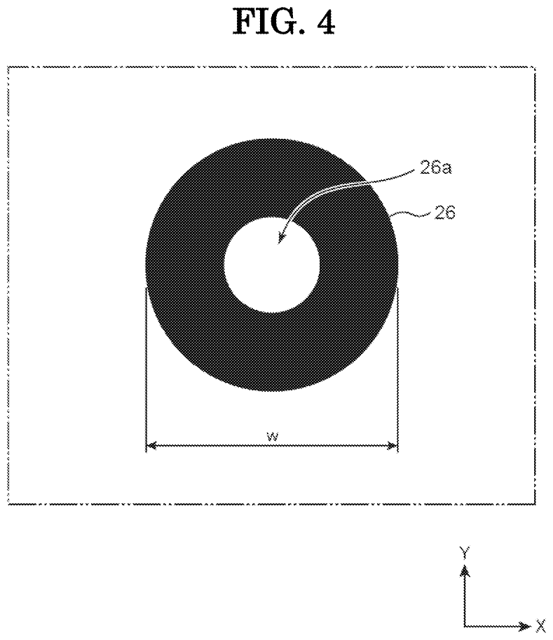

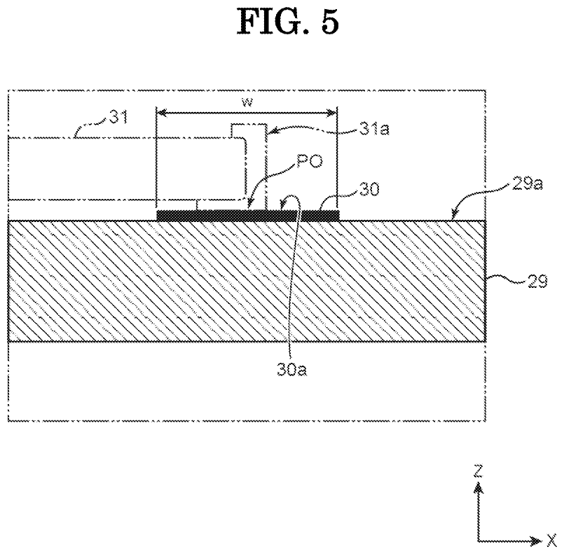

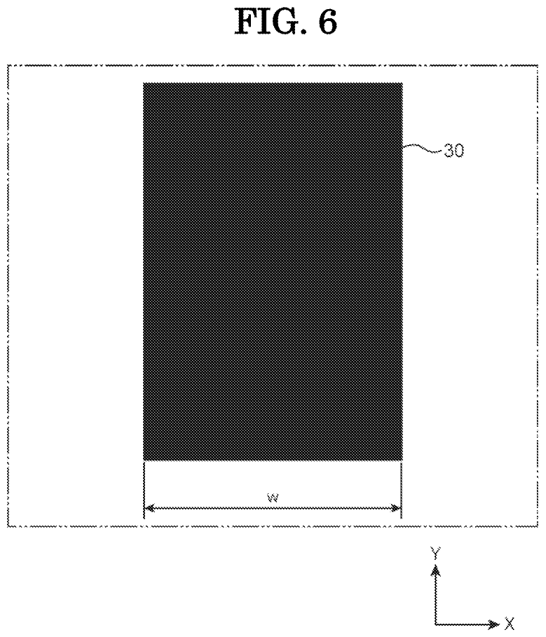

Shapes of lands 26, 27, and 30 provided on main surfaces 25a, 25b, 29a of printed circuit boards 25, 29 respectively will be described with reference to FIG. 3 to FIG. 6. Here, FIG. 3 and FIG. 4 show the through-hole type lands 26, 27, and FIG. 5 and FIG. 6 shows the surface mount type land 30.

(1) Through-Hole Type Lands 26, 27.

As shown in FIG. 3 and FIG. 4, the land 26 is provided on one main surface 25a of the printed circuit board 25, and the land 27 is provided on the other main surface 25b of the printed circuit board 25. The printed circuit board 25 and the lands 26, 27 are formed with holes 25c, 26a, 27a. The holes 25c, 26a, 27a are the part where a lead 28 is inserted therethrough.

Each of the lands 26, 27 has a substantially annular and planar shape. Although FIG. 4 illustrates only the land 26, the land 27 has the same planar shape. Further, while soldering, the tip 16a of the soldering iron 16 comes into contact with the land 26.

The operator inputs a coordinate (x, z) of an end position P0 and an outer diameter (land width) w of the land 26 via the touch panel 23a. The end position P0 represents an intersection between an opening on an upper surface 26b defining the hole 26a in the land 26 and an imaginary line connecting the centers of the hole 26a and the hole 27a.

In the embodiment, when the land is a through-hole type, the outer diameter (land width) w of the land 26 is regarded as a “size of the workpiece”.

(2) Surface Mount Type Land 30 Based on Surface Mount

As shown in FIG. 5 and FIG. 6, the land 30 is provided on one main surface 29a of the printed circuit board 29. The land 30 has a substantially rectangular (quadrangular) and planar shape.

The operator inputs a coordinate (x, z) of an end position P0 and a land width w of the land 30 via the touch panel 23a. The end position P0 represents a position on an upper surface 30a of the land 30 where a terminal 31a of a chip component 31 is located.

In the embodiment, a short side of the rectangular and planar shape is defined as the land width w of the land 30 (see FIG. 6).

In the embodiment, when the land is a surface mount type, the land width w of the land 30 is regarded as a “size of the workpiece”.

3. Tip Evacuation Angle θ

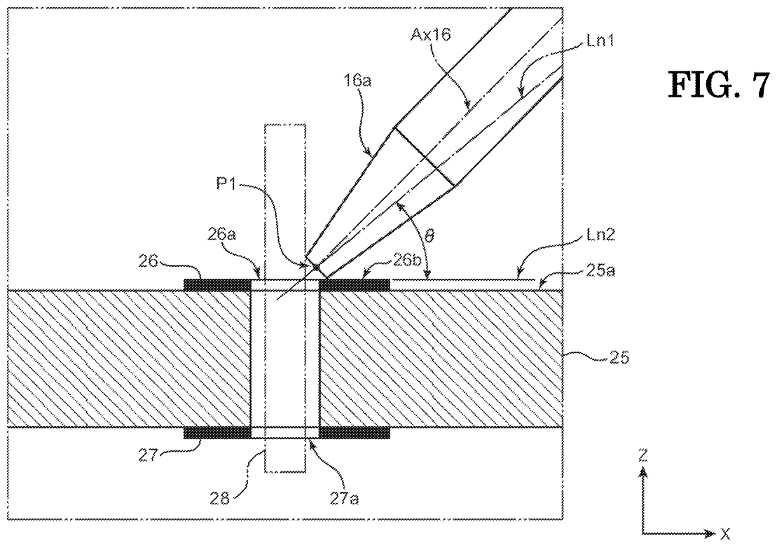

A tip evacuation angle θ to be input by the operator via the touch panel 23a will be described with reference to FIG. 7.

As shown in FIG. 7, the soldering is performed by feeding a predetermined amount of the solder wire 18 in a state where the tip 16a of the soldering iron 16 is in contact with the lead 28 and the land 26. The position of a distal end of the tip 16a while soldering, will be the position (soldering position) P1 where the soldering iron 16 starts to evacuate.

Subsequently, the soldering iron 16 is evacuated so that the tip 16a of the soldering iron 16 withdraws along a tip evacuation route Ln1. The tip evacuation route Ln1 is set in such a way as to form an angle (tip evacuation angle) θ to an imaginary line Ln2 along the upper surface 26b of the land 26. The tip evacuation angle θ is an angle set in such a manner so as to avoid a contact between surrounding chip components and the soldering iron 16.

The tip evacuation angle θ is set by the ratio between a speed (moving speed along arrow A1 shown in FIG. 1) of the linear actuator 13 and a speed (moving speed along arrow A2 shown in FIG. 1) of the linear actuator 14.

As shown in FIG. 7, in the example of the embodiment, the axis Ax16 of the tip 16a of the soldering iron 16 is different from the tip evacuation route Ln1. However, the axis and the route may be the same. In other words, the axis Ax16 of the tip 16a and the tip evacuation route Ln1 may match each other depending on the attachment angle of the soldering iron 16 to the iron support member 15.

The operator inputs the tip evacuation angle θ via the touch panel 23a in consideration of a surrounding circumstance of the land 26. The operator can input a spatial coordinate in place of the tip evacuation angle θ. When the operator inputs the spatial coordinate, the controller 22 calculates, based on the input coordinate, the tip evacuation angle θ. Here, the spatial coordinate to be input by the operator may be a coordinate at any position as long as the position is on the tip evacuation route Ln1.

Moreover, in the description, an “X direction” includes the tip evacuation route Ln1 and represents a direction parallel to the upper surface 26b of the land 26 on an imaginary plane perpendicular to the main surface 25a of the printed circuit board 25, and a “Z direction” represents a direction orthogonal to the main surface 25a of the printed circuit board 25 or the upper surface 26b of the land 26.

4. Tip Shape Offset Amount

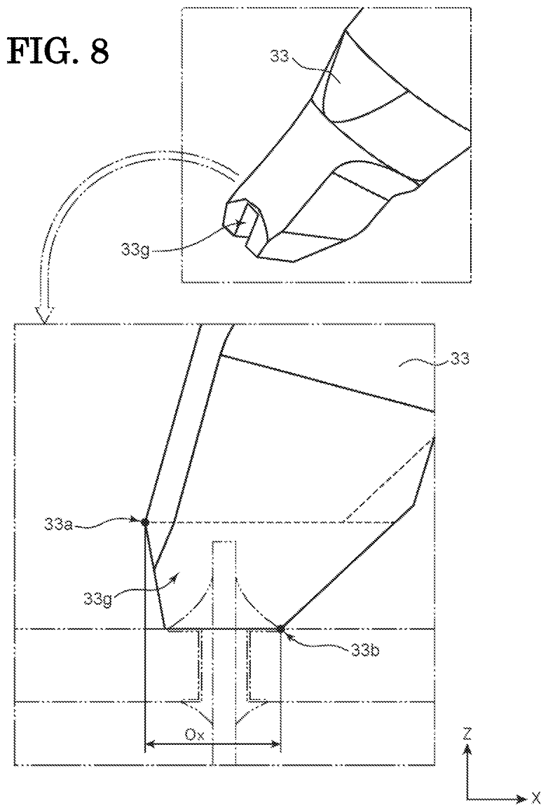

A shape of the tip 16a input by the operator via the touch panel 23a and an offset amount (Ox, Oz) based on the tip shape will be described with reference to FIG. 8 to FIG. 10. FIG. 8 to FIG. 10 respectively show three examples of the shape of the tip 16a.

(1) First Type

As shown in FIG. 8, a tip 33 of a first type has a flat distal end. The distal end of the tip 33 has a size larger than an outer diameter (land width) of the land. The distal end of the tip 33 of the first type is further formed with a groove 33g. The groove 33g is formed so the groove bottom is parallel to the distal end.

For the type of tip 33 as shown in FIG. 8, a distance between a position (groove bottom edge) 33a on one side in the X direction at the groove bottom of the groove 33g and a position 33b on the other side in the X direction at the flat distal end is set as an offset amount Ox.

Although only the amount Ox of the offset amounts (Ox, Oz) is shown in FIG. 8, the distance between the position 33a and the position 33b results in being divided into a component Ox in the X direction and a component Oz in the Z direction depending on the posture of the soldering iron (attachment angle of the soldering iron to the iron support member 15).

The “X direction” and the “Z direction” in FIG. 8 are defined in the same manner as those described with reference to FIG. 7.

(2) Second Type

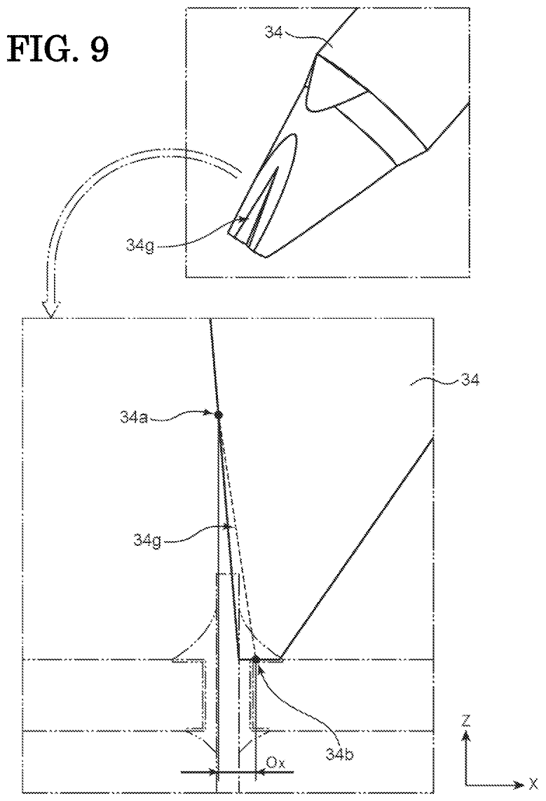

As shown in FIG. 9, a tip 34 of a second type also has a flat distal end. The distal end of the tip 34 is smaller than the distal end of the tip 33 of the first type described with reference to FIG. 8.

The tip 34 of the second type is formed with a groove 34g. The groove 34g of the tip 34 differs from the groove 33g of the tip 33 of the first type in that a groove bottom is formed so it will diagonally intersect the distal end.

For the tip 34 of the type shown in FIG. 9, a distance between a position (groove bottom edge) 34a on one side in the X direction at the groove bottom of the groove 34g and a position (groove bottom edge) 34b on the other side in the X direction is set as the offset amount Ox.

Although only the amount Ox of the offset amounts (Ox, Oz) is shown in FIG. 9, the distance between the position 34a and the position 34b results in being divided into a component Ox in the X direction and a component Oz in the Z direction depending on the posture of the soldering iron (attachment angle of the soldering iron to the iron support member 15).

The “X direction” and the “Z direction” in FIG. 9 are defined in the same manner as those described with reference to FIG. 7.

(3) Third Type

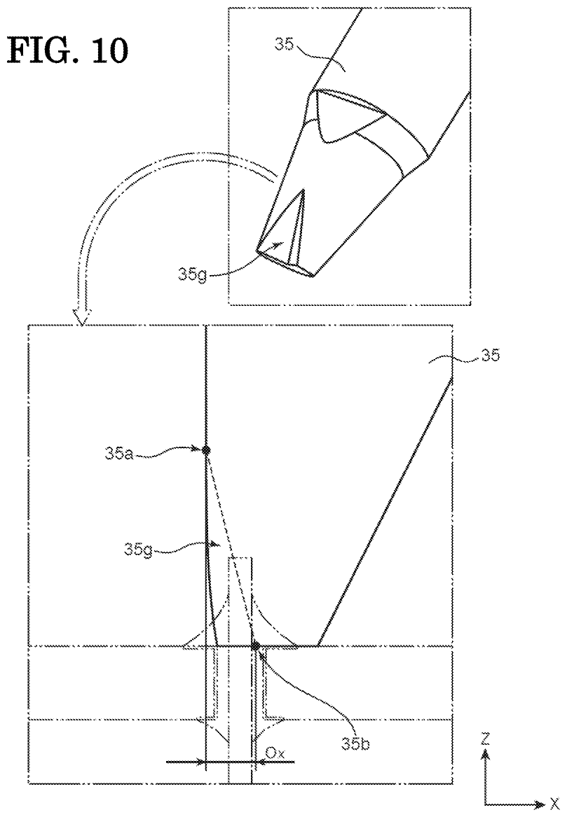

As shown in FIG. 10, a tip 35 of a third type also has a flat distal end. The distal end of the tip 35 is smaller than the distal end of the tip 33 of the first type described with reference to FIG. 8 and larger than the tip 34 described with reference to FIG. 9.

The tip 35 of the third type is formed with a groove 35g. The groove 35g of the tip 35 is defined by a groove bottom diagonally intersecting the distal end in the same manner as the tip 34 of the second type.

For the tip 35 of the type shown in FIG. 10, a distance between a position (groove bottom edge) 35a on one side in the X direction at a groove bottom of the groove 35g and a position (groove bottom edge) 35b on the other side in the X direction is set as the offset amount Ox.

Although only the amount Ox of the offset amounts (Ox, Oz) is shown in FIG. 10, the distance between the position 35a and the position 35b results in being divided into a component Ox in the X direction and a component Oz in the Z direction depending on the posture of the soldering iron (attachment angle of the soldering iron to the iron support member 15).

The “X direction” and the “Z direction” in FIG. 10 are defined in the same manner as those described with reference to FIG. 7.

5. Setting of Specific Position P3

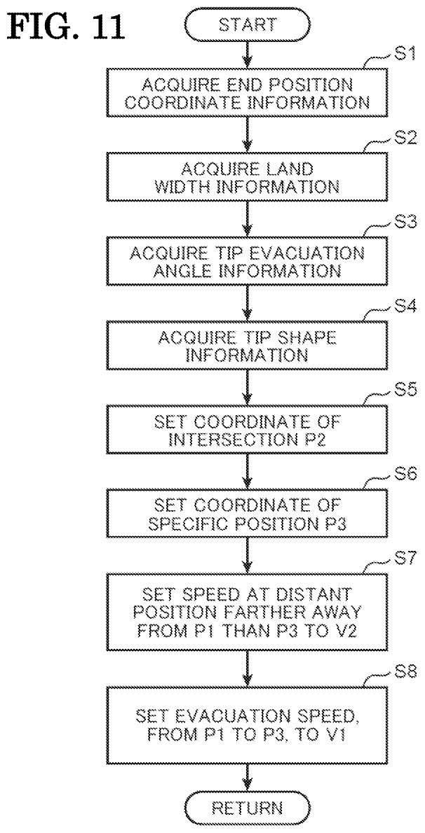

The coordinate setting part 221 of the controller 22 sets a position at a predetermined distance from a soldering position P1 on the tip evacuation route Ln1 of the tip 16a as a specific position P3. A way of setting the specific position P3 of the tip 16a by the coordinate setting part 221 of the controller 22 will be described with reference to FIG. 11 to FIG. 13.

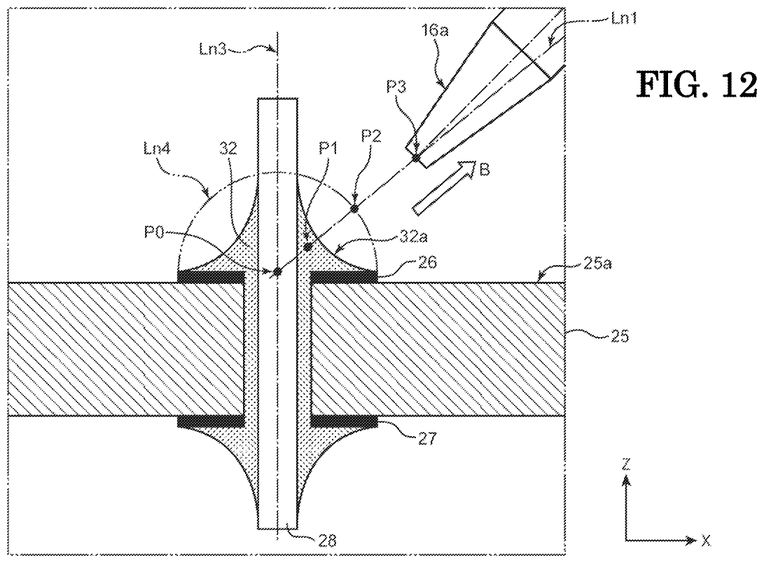

As shown in FIG. 11 and FIG. 12, the controller 22 acquires a coordinate (x, z) of an end position P0 input by the operator (step S1). Similarly, the controller 22 further acquires information about an outer diameter (land width) w of the land 26 and a tip evacuation angle θ from an input by the operator (steps S2, S3). The controller 22 further acquires information about a shape of the tip input by the operator (step S4).

Next, the coordinate setting part 221 of the controller 22 sets a coordinate (x′, z′) of an intersection position P2 shown in FIG. 12 (step S5). Specifically, the coordinate setting part 221 sets an estimated solder layer outline Ln4 shown in FIG. 12 from the outer diameter w of the land 26, and then sets the coordinate (x′, z′) of the intersection position P2 by using the following equation (1):

$$( {x}^{′} , {z}^{′} ) = ( x + w / 2 \times cos θ , z + w / 2 \times sin θ ) \qquad ( 1 )$$

Here, a solder layer 32 ideally has an outer surface 32a recessed inward as shown in FIG. 12. In contrast, in consideration of a shape variation of the solder layer 32, the coordinate setting part 221 sets a semicircle having a diameter of the land width w with a center at the end position P0 as the estimated solder layer outline Ln4. As shown in FIG. 12, the semicircle includes the tip evacuation route Ln1, and is set on an imaginary plane perpendicular to the main surface 25a of the printed circuit board 25.

The coordinate setting part 221 sets an intersection between the estimated solder layer outline Ln4 set in the aforementioned manner and the tip evacuation route Ln1 as the intersection position P2.

Subsequently, the coordinate setting part 221 sets a coordinate (x″, z″) of the specific position P3 by using the following equation (2) in consideration of a tip shape offset amount (Ox, Oz) (step S6):

$$( {x}^{′′} , {z}^{′′} ) = ( x + w / 2 \times cos θ + Ox , z + w / 2 \times sin θ + Oz ) \qquad ( 2 )$$

Here, the tip shape offset amount (Ox, Oz) is set by the tip shape offset setting part 222, based on the information about the input shape of the tip. The set tip shape offset amount (Ox, Oz) is sent to the coordinate setting part 221. The tip shape offset setting part 222, may store for instance, a table in which a part number of a tip and its corresponding tip shape offset amount (Ox, Oz) are associated with each other, and sets the tip shape offset amount (Ox, Oz) with reference to the table.

The specific position P3 may be set outside the estimated solder layer outline Ln4 as shown in FIG. 12 in consideration of the tip shape offset amount (Ox, Oz) in the setting of the coordinate (x″, z″). The tip shape offset amount may indicate (0, 0) depending on the shape of the tip 16a. In this case, the specific position P3 is set on the estimated solder layer outline Ln4.

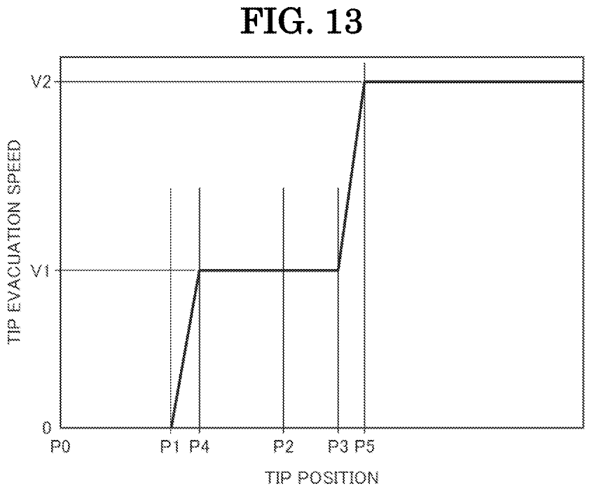

Subsequently, the evacuation speed setting part 223 of the controller 22 sets a speed V2, which is a speed of the tip 16a in evacuation at a distant position P5 farther away from the soldering position P1 than the specific position P3 (step S7). As shown in FIG. 13, the distant position P5 is farther away from the soldering position P1 than the specific position P3.

Next, the evacuation speed setting part 223 sets a speed V1, which is a speed of the tip 16a in evacuation from the soldering position P1 to the specific position P3 (step S8). Here, the speed V1 corresponds to an “evacuation speed” and is slower than the speed V2.

The evacuation speed setting part 223 stores, in advance, the speed V1 and the speed V2. For example, the speed V1=40 mm/sec and the speed V2=100 mm/sec.

In evacuation of the tip 16a from the soldering position P1 along the arrow B as shown in FIG. 12, the speed V1 in a region from the soldering position P1 to the specific position P3 is set to a low speed which is lower than the speed (predetermined speed) V2 in a region further away from the distant position P5 as shown in the chart in FIG. 13. Specifically, as shown in FIG. 13, the speed is accelerated from the soldering position P1 and reaches the speed V1 at the position P4. Moreover, the speed of the soldering iron 16 during the evacuation is maintained at the low speed (speed V1) until the tip reaches the specific position P3 after passing through the intersection position P2.

When the tip 16a reaches the specific position P3, the speed of the soldering iron 16 is accelerated and the speed of the tip 16a reaches the speed V2 at the distant position P5. Thereafter, the speed in the region farther away from the soldering position P1 than the distant position P5 is maintained at the speed V2.

Although the embodiment shows the exemplary state where the end position P0 and the soldering position P1 are away from each other as shown in FIG. 12, the soldering position P1 may match the end position P0 depending on the shape of the tip of the soldering iron. For instance, in use of the soldering iron having the tip 33 described with reference to FIG. 8, the lead 28 is accommodated in the groove 33g while soldering, so the soldering position P1 substantially matches the end position P0.

6. Solder Feed Volume

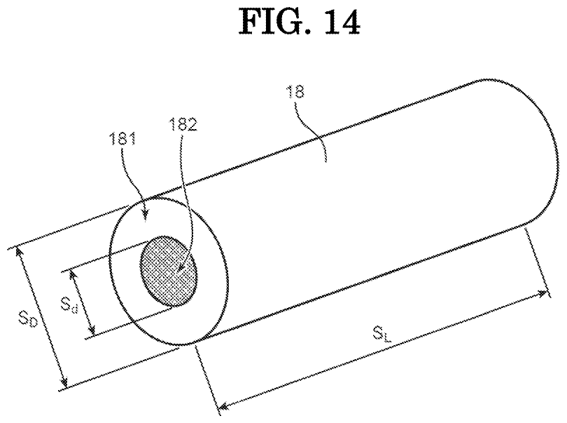

The operator further inputs information (feed amount information) about an amount of solder feed via the touch panel (input section) 23a of the input receiving part 23. The solder feed volume calculation part 224 of the controller 22 calculates a volume of solder 181 excluding volume of flux 182 filled in the solder wire 18. A way of calculating a solder feed volume to be executed by the solder feed volume calculation part 224 will be described with reference to FIG. 14.

As shown in FIG. 14, the solder wire 18 includes solder 181 having an annular end surface and flux 182 filling the inner part of the solder 181 and having an end surface in a circle-like shape. The solder wire 18 has a diameter S_{D}, and the flux 182 has a diameter S_{d}. An amount of solder to be fed per soldering is denoted as S_{L}. The solder feed volume calculation part 224 calculates the volume V_{f} of flux 182 by using the following equation (3):

$${V}_{f} = ( π \times {S}_{d}^{2} \times {S}_{L} ) / 4 \qquad ( 3 )$$

Subsequently, the solder feed volume calculation part 224 calculates the solder feed volume Vₛ by using the following equation (4):

$${V}_{s} = ( π \times {S}_{D}^{2} \times {S}_{L} ) / 4 - {V}_{f} = ( π \times {S}_{D}^{2} \times {S}_{L} ) / 4 - ( π \times {S}_{d}^{2} \times {S}_{L} ) / 4 \qquad ( 4 )$$

In the soldering device 1 according to the embodiment, the solder feed volume calculation part 224 may also send out the solder feed volume Vₛ calculated by using the equation (4) to the coordinate setting part 221.

The coordinate setting part 221 can further calculate the outer surface 32a of the solder layer 32 shown in FIG. 12 by using the received solder feed volume Vₛ, land width w of each of the lands 26, 30, and other parameters. Further, the coordinate setting part 221 may calculate the coordinate (x′, z′) from the calculated outer surface 32a of the solder layer 32. Moreover, the coordinate (x″, z″) of the specific position P3 is settable by using the calculated coordinate (x′, z′) and the tip shape offset (Ox, Oz).

7. Evacuation Speed V1

As described above, the evacuation speed setting part 223 of the controller 22 sets the evacuation speed of the tip 16a from the soldering position P1 to the specific position P3 to speed V1, and sets the speed of the tip 16a at the distant position P5 farther away from the soldering position P1 than the specific position P3 to speed V2. Of these speeds V1 and V2, confirmation experiments performed for defining the low evacuation speed V1 which will influence solder scattering significantly will be described with reference to FIG. 15 to FIG. 18.

(1) Tip 36 of Soldering Iron Used in Confirmation Experiments

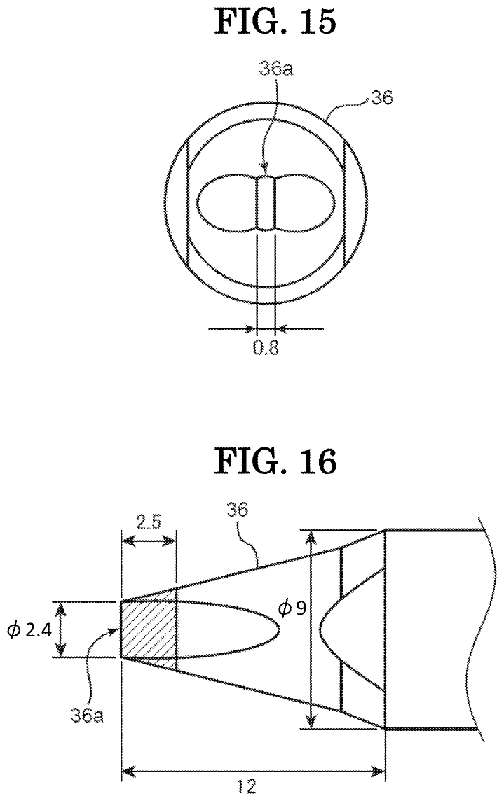

As shown in FIG. 15 and FIG. 16, a tip 36 of a soldering iron used in the confirmation experiments has a distal end 36a having a rectangular shape of 2.4 mm×0.8 mm. The distal end 36a has a length of 2.5 mm.

The tip 36 has a shape like a screwdriver or a chisel, such a shape that it can be obtained by cutting a substantial frustum with a gradually increasing diameter from the distal end 36a toward a proximal end in two directions. The tip 36 has a length of 12 mm, and the proximal end has an outer diameter of 9 mm.

(2) Evacuation Speed V1 and Number of Solder Scatterings

Experiment conditions for the confirmation experiments are shown in the following table.

| Tip temperature | 350 | [° C.] |
|---|---|---|
| Tip angle | 75 | [°] |
| Solder alloy | Sn—3.0Ag—0.5Cu | |
| Solder diameter | φ1.0 | [mm] |
| Solder feed length | 20.0 | [mm] |
| Solder feed speed | 10.0 | [mm/s] |
| Heating time | 0.5 | [s] |
| Tip evacuation length | 20.0 | [mm] |
| Tip evacuation angle | 45 | [°] |
| Tip evacuation speed | 10.0~100.0 | [mm/s] |

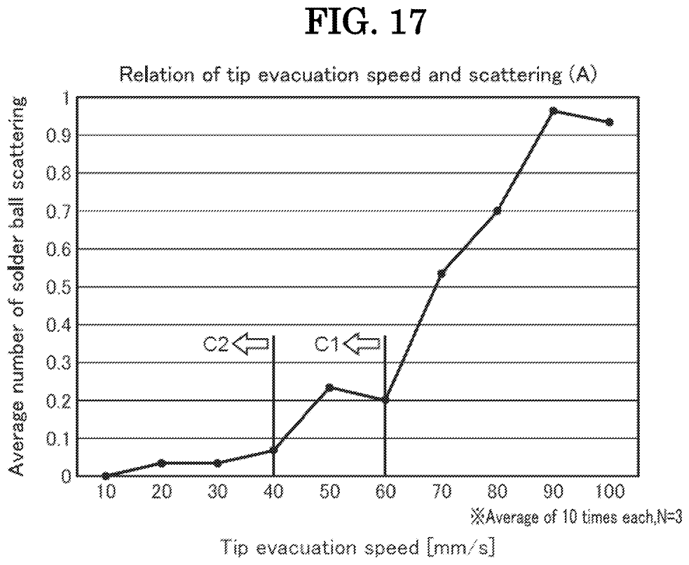

First, FIG. 17 shows results of an experiment using solder of type A.

As shown in FIG. 17, use of the solder of type A at the evacuation speed V1 exceeding 60 mm/sec resulted in the significantly large number of solder scatterings. In other words, the number of solder scatterings was relatively small at the speed V1 in a speed range (denoted by an arrow C1) of 60 mm/sec or lower relevant to the tip evacuation.

Furthermore, the number of solder scatterings was significantly small at the evacuation speed V1 of 40 mm/sec or lower (in a speed range denoted by an arrow C2).

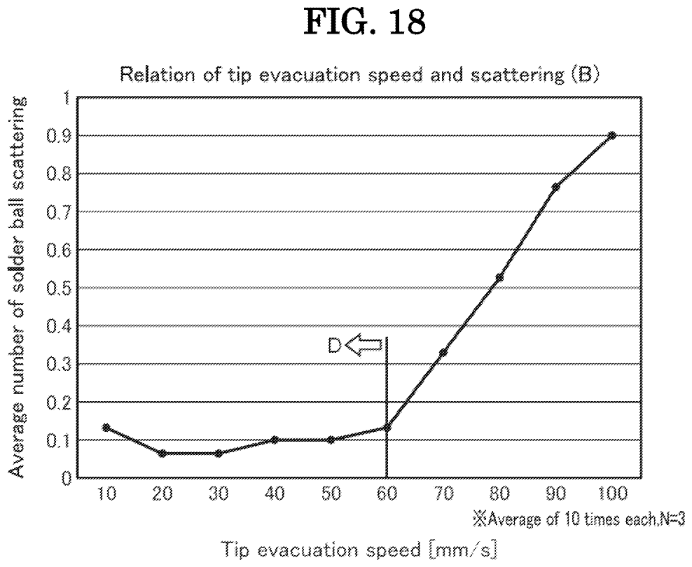

Next, results of an experiment using solder of type B are shown in FIG. 18.

As shown in FIG. 18, use of the solder of type B at the evacuation speed V1 in the speed range (denoted by an arrow D) of 60 mm/sec or lower resulted in the small number of solder scatterings.

(3) Brief Summary

The evacuation speed V1 is set to 40 mm/sec in the soldering device 1 according to the embodiment in view of the results of the experiments shown in FIG. 17 and FIG. 18. However, as described with reference to FIG. 17, the evacuation speed V1 of 60 mm/sec is adoptable in use of the solder of type A from the viewpoint of the achieved relatively small number of solder scatterings at the evacuation speed V1 of 60 mm/sec or lower.

8. Advantageous Effects

In the soldering device 1 according to the embodiment, the evacuation speed V1 of the tip 16a in evacuation from the soldering position P1 to the specific position P3 is lower than the speed (predetermined speed) V2 of the tip 16a in evacuation at a distant position farther away from the soldering position P1 than the distant position P5. Hence, the soldering device 1 can more effectively avoid an unnecessarily prolonged tact time than a configuration where an evacuation speed of a tip 16a is uniformly maintained.

The soldering device 1 further sets, based on the size information (land width w), the coordinate of the specific position P3. Therefore, the soldering device 1 can more effectively suppress the soldering scattering in the evacuation of the soldering iron 16 while avoiding unnecessary prolonged tact time than a configuration where a tip is evacuated at a low speed to a position at a distance determined depending on a size of a cam mechanism like JP-U-S62-015863.

In the soldering device 1, the land width w is regarded as the size of the workpiece. The land width w is defined depending on the size of the workpiece to be joined, and thus the coordinate (x″, z″) of the specific position P3 is accurately settable by using the land width w as well.

In the soldering device 1, the coordinate (x″, z″) of the specific position P3 is set based on the estimated solder layer outline Ln4 having the semicircular shape as shown in FIG. 12. This enables the setting of the specific position P3 in an outer region than the outer surface 32a of the solder layer 32 joining the land 26 and the workpiece (lead 28) to each other. Accordingly, the soldering device 1 is effective to suppress the solder scattering in the evacuation of the soldering iron 16 while avoiding unnecessarily prolonged tact time.

In the soldering device 1, the coordinate (x″, z″) of the specific position P3 is set in consideration of the shape of the tip 16a by further using the tip shape offset (Ox, Oz). This setting results in reliable suppression of the solder scattering in the evacuation of the soldering iron 16 even in use of any of various soldering irons 16 with tips 16a having different shapes.

In the embodiment, the exemplary configuration where the lead 28 is soldered to the through-hole lands 26, 27 has been described in the embodiment. Instead, the workpiece can be soldered to the surface mount land 30 in the same manner. The same effect as that described above may be obtained by soldering the workpiece to the surface mount land 30.

### First Modification

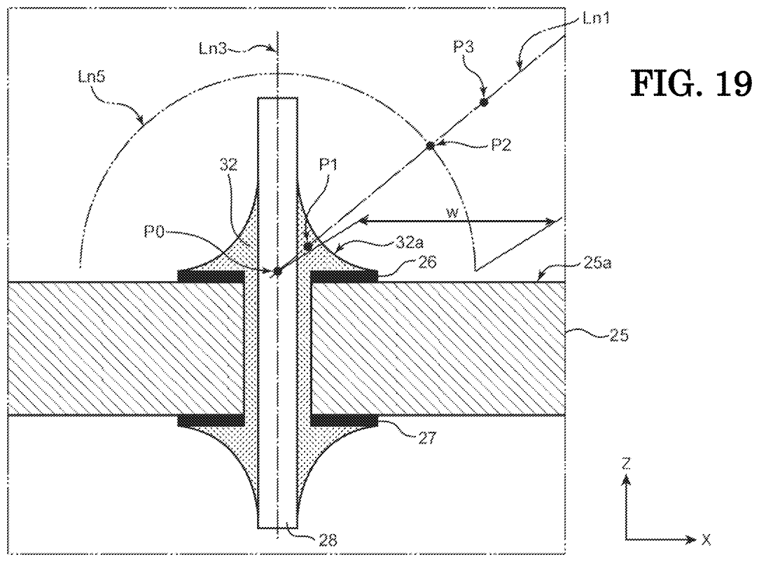

A way of setting a coordinate (x″, z″) of a specific position P3 according to a first modification will be described with reference to FIG. 19. A soldering device according to the modification has the same configuration as that of the soldering device 1 according to the embodiment except the way of setting the coordinate (x″, z″) of the specific position P3 to be executed by a coordinate setting part 221.

As shown in FIG. 19, the coordinate setting part 221 included in a controller 22 sets a coordinate (x′, z′) of an intersection position P2, based on a coordinate (x, z) of an end position P0, a land width w of a land 26, and a tip evacuation angle θ, each input by an operator. Specifically, as shown in FIG. 19, the coordinate setting part 221 sets, as an estimated solder layer outline Ln5, a semicircle having a radius representing a land width w (having a diameter twice as large as the land width w) with a center at the end position P0. In the modification as well, as shown in FIG. 19, the semicircle includes a tip evacuation route Ln1 and is set on an imaginary plane perpendicular to a main surface 25a of a printed circuit board 25.

Next, the coordinate setting part 221 sets the coordinate (x′, z′) of the intersection position P2 between the estimated solder layer outline Ln5 and the tip evacuation route Ln1, based on the following equation (5):

$$( {x}^{′} , {z}^{′} ) = ( x + w \times cos θ , z + w \times sin θ ) \qquad ( 5 )$$

Here, the difference from the embodiment is seen in that the estimated solder layer outline Ln5 is defined by the semicircle having the radius w with the center at the end position P0 as shown in FIG. 19. That is, in the modification, the estimated solder layer outline Ln5 is set in further consideration of safety concerning the outer surface 32a of the solder layer 32.

Subsequently, the coordinate setting part 221 sets the coordinate (x″, z″) of the specific position P3 by using the following equation (6) in consideration of a tip shape offset amount (Ox, Oz):

$$( {x}^{′′} , {z}^{′′} ) = ( x + w \times cos θ + Ox , z + w \times sin θ + Oz ) \qquad ( 6 )$$

Although the estimated solder layer outline Ln5 is set based on the semicircle having the radius w in the modification, another modification is adoptable for setting the estimated solder layer outline. Specifically, the estimated solder layer outline may be set by adopting a numerical value falling within the range of w/2 to w as the radius.

The soldering device according to the modification can provide the same advantageous effect as that of the soldering device 1 according to the embodiment. Moreover, the modification including the estimated solder layer outline Ln5 set based on the semicircle having the radius w is further effective to suppress the solder scattering when there is a large variation in the outer surface 32a of the solder layer 32.

### Second Modification

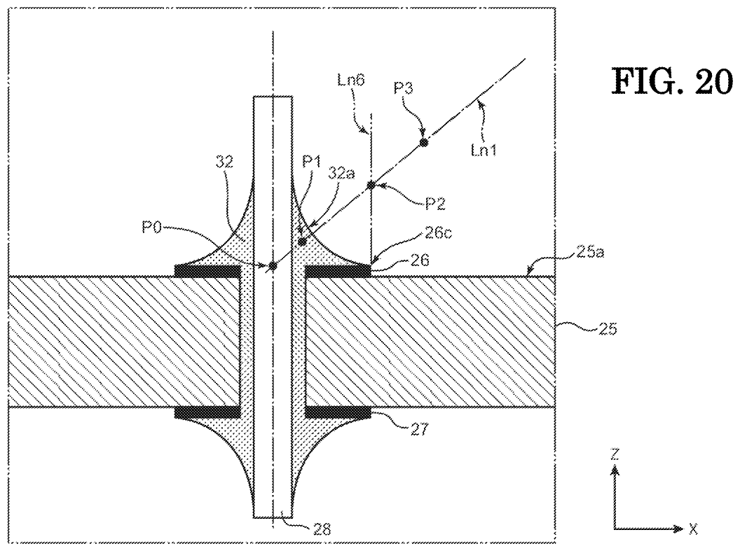

A way of setting a coordinate (x″, z″) of a specific position P3 according to a second modification will be described with reference to FIG. 20. A soldering device according to the modification also has the same configuration as that of the soldering device 1 according to the embodiment except the way of setting the coordinate (x″, z″) of the specific position P3 to be executed by a coordinate setting part 221.

As shown in FIG. 20, the coordinate setting part 221 included in a controller 22 sets a coordinate (x′, z′) of an intersection position P2, based on a coordinate (x, z) of an end position P0, a land width w of a land 26, and a tip evacuation angle θ, each input by the operator. Specifically, the coordinate setting part 221 sets an estimated solder layer outline Ln6 passing through an outer edge 26c of a land 26 and extending orthogonally to a main surface 25a of a printed circuit board 25.

Subsequently, the coordinate setting part 221 sets an intersection position P2, a position where the estimated solder layer outline Ln6 set in the aforementioned manner and a tip evacuation route Ln1 intersects, and sets the coordinate of the intersection position P2 to (x′, z′). The coordinate setting part 221 then sets the coordinate (x″, z″) of the specific position P3 in consideration of a tip shape offset amount (Ox, Oz).

Although in the modification, the estimated solder layer outline Ln6 is set passing through the outer edge 26c of the land 26, an estimated solder layer outline may be set passing through a radially outer region of the land 26 than the outer edge 26c of the land 26.

The soldering device according to this modification can also provide the same advantageous effect as that of the soldering device 1 according to the embodiment.

### Third Modification

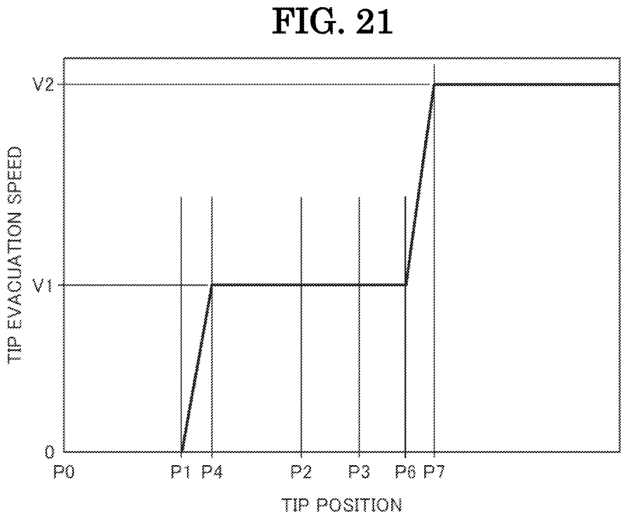

An evacuation state of a soldering iron 16 included in a soldering device according to a third modification will be described with reference to FIG. 21. The modification differs from the embodiment in setting of a speed relevant to evacuation of a tip 16a at a position farther away from a soldering position P1 than a specific position P3.

As shown in FIG. 21, in the soldering device according to the modification, the speed of the tip 16a of the soldering iron 16 is accelerated from the soldering position P1 to reach an evacuation speed V1 at a position P4. The evacuation speed V1 is maintained from the position P4 to a position P6 in the modification. Here, the position P6 is set to the position farther away from the soldering position P1 than the specific position P3.

In the soldering device according to the modification, when the tip 16a reaches the position P6, the speed relevant to the evacuation is accelerated and at a position P7, reach to a speed V2 representing a predetermined speed. Thereafter, the speed is maintained at the speed V2 during the evacuation. In the modification, the position P7 serves as a distant position farther away from the soldering position P1 than the specific position P3.

The soldering device according to the modification can provide the same advantageous effect as that of the soldering device 1 according to the embodiment as well. In this modification, the tip 16a evacuate at a high speed (speed V2) from the distant position P7 which is farther away from the soldering position P1 than the specific position P3. Hence, an offset amount based on the shape of the tip 16a is not necessarily taken into consideration. Specifically, by setting the speed relevant to the evacuation of the tip 16a at the distant position P7 which is farther away from the soldering position P1 than the specific position P3 to higher speed V2, it achieves suppression of the solder scattering even without consideration of the offset amount based on the shape of the tip 16a.

### Fourth Modification

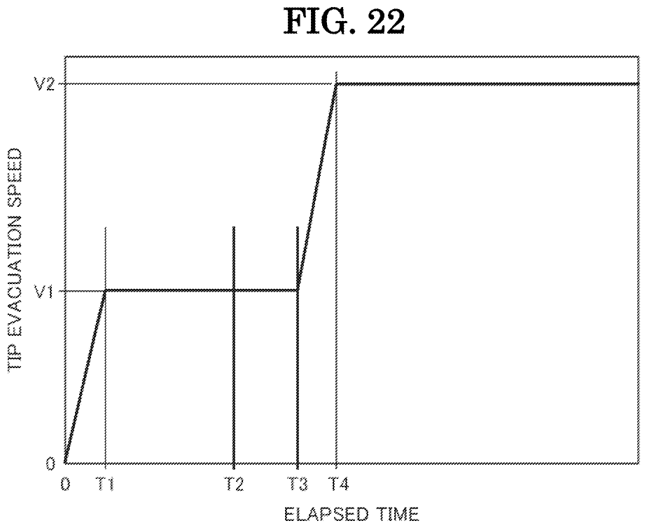

An evacuation state of a soldering iron 16 included in a soldering device according to a fourth modification will be described with reference to FIG. 22. The modification differs from the third modification in that a speed relevant to evacuation of a tip 16a is controlled at an evacuation speed V1 until a lapse of a time required for the tip 16a to reach a position P6 from a soldering position P1 passing through a specific position P3.

As shown in FIG. 22, a controller 22 starts to measure a time at a start of the evacuation of the tip 16a from the soldering position P1 in the soldering device according to the modification. Although not particularly mentioned above, the controller 22 has a timer.

The controller 22 causes the soldering iron 16 to start to evacuate at the same time as the start of the time measurement, and accelerates a speed relevant to the evacuation of the soldering iron 16 at a time T1 to reach a speed V1. The controller 22 then maintains the speed relevant to the evacuation of the soldering iron 16 at the speed V1 passing a time T2 until reaching a time T3. The time T2 represents a time when the tip 16a passes through the specific position P3, and the time T3 represents a time when the tip 16a reaches the position P6 (see FIG. 21). Specifically, in the modification, the controller 22 controls a speed relevant to the evacuation of the tip 16a at the evacuation speed V1 which is a low speed until a lapse of a predetermined time (T3) required for the tip 16a to leave the soldering position P1 and reach the position P6 which is farther away from the soldering position P1 than the specific position P3.

The controller 22 accelerates the speed relevant to the evacuation of the soldering iron 16 so that the speed relevant to the evacuation of the soldering iron 16 reaches a speed V2 at a time T4 after the lapse of the time T3. The controller 22 then maintains the speed relevant to the evacuation of the soldering iron 16 at speed V2 serving as a predetermined speed at the time T4 and thereafter.

The tip 16a of the soldering iron 16 reaches the position P7 shown in FIG. 21 at time T4.

The soldering device according to the modification can provide the same advantageous effect as that of the soldering device 1 according to the embodiment.

Although in this modification, the tip 16a is defined to reach the specific position P3 at the time T2 and to evacuate at the speed V1 until the time T3, the speed relevant to the evacuation of the tip 16a may start to accelerate toward the speed V2 at the time T2.

### Other Modifications

Although no specific configuration of each of the actuators 13, 14, 20 has been referred to in the embodiment and the first to fourth modifications, actuators having various configurations are adoptable. For instance, adoptable actuators include an actuator having a linear motor, an actuator having a motor connected to a ball screw, and further an actuator having an air cylinder or a hydraulic cylinder.

Although the three actuators 13, 14, 20 are used for moving the soldering iron 16 and the workpiece (printed circuit board 25, 29) relative to each other in the embodiment and the first to fourth modifications, the present invention is not limited thereto. For example, a soldering device having three or more actuators may be adoptable. Additionally, another actuator dedicated to evacuate the tip 16a of the soldering iron 16 to the specific position P3 may be provided.

### SUMMARY

A soldering device according to one aspect of the present disclosure is a soldering device for joining a workpiece to a land provided on a main surface of a printed circuit board. The soldering device according to this aspect includes: a soldering iron having a tip which is heatable; a driver for moving the soldering iron; an input receiving part for receiving an input of size information about a size of a workpiece; and a controller for controlling the driver.

The controller includes a coordinate setting part and an evacuation speed setting part. The coordinate setting part sets, based on the size information, a coordinate of a specific position at a predetermined distance from a soldering position where the tip performs soldering. The evacuation speed setting part sets, to a predetermined speed, a speed of the tip in evacuation at a distant position which is farther away from the soldering position than the specific position, and sets, to a speed slower than the predetermined speed, an evacuation speed of the tip in evacuation from the soldering position to the specific position.

In the soldering device according to the aspect, the speed (predetermined speed) of the tip at the distant position farther away from the soldering position than the specific position is faster than the evacuation speed of the tip from the soldering position to the specific position. Hence, the soldering device according to the aspect can more effectively avoid an unnecessarily prolonged tact time than a configuration where a speed of a soldering iron in evacuation is maintained at a low speed.

Besides, the soldering device according to the aspect achieves suppression of solder scattering occurring when the soldering iron leaves the soldering position by setting the evacuation speed (first speed) of the tip in evacuation from the soldering position to the specific position to the low speed which is slower than the speed (second speed) at the distant position.

The soldering device according to the aspect further sets, based on the size information (information about the size of the workpiece), the coordinate of the specific position. Therefore, the soldering device according to the aspect can more effectively suppress the soldering scattering in the evacuation of the soldering iron while avoiding an unnecessary prolonged tact time than a configuration where a tip is evacuated at a low speed only at a distance determined depending on the size of a cam mechanism like JP-U-S62-015863.

In the soldering device according to the aspect, the input receiving part may receive width information about a land width of the land as the size information.

As described above, the coordinate of the specific position is accurately settable even by using the land width as the size of the workpiece as well. In other words, since the land width is defined depending on the size of the workpiece to be joined, the coordinate of the specific position is accurately settable by using the land width as the size of the workpiece.

In the soldering device according to the aspect, the coordinate setting part may set the coordinate of the specific position on an outer side in an evacuation direction of the tip than a semicircular imaginary region defined by the land width having a center of the semicircular imaginary region at a center of the land width.

The setting of the coordinate of the specific position based on the semicircular imaginary region leads to successful setting of the specific position in an outer region than the outer surface of the solder layer for joining the land and the workpiece to each other. Accordingly, adoption of this configuration is effective to suppress the solder scattering in the evacuation of the soldering iron while avoiding an unnecessarily prolonged tact time.

In the soldering device according to the aspect, the coordinate setting part may set the coordinate of the specific position in the semicircular imaginary region having a radius of between ½ times and 1 times the land width.

The setting of the specific position in the specific numerical range as described above is further effective to suppress the solder scattering in the evacuation of the soldering iron while avoiding an unnecessarily prolonged tact time. An outer surface of an actual solder layer is empirically known to exist inside of the imaginary region. Therefore, the definition of the radius of the semicircular imaginary region in the range of between ½ times and 1 times the land width w can ensure the suppression of the solder scattering in the evacuation of the soldering iron even in consideration of a shape variation of the solder layer.

In the soldering device according to the aspect, the input receiving part may further receive angle information about a tip evacuation angle representing an angle defined by a surface of the land and an evacuation route of the tip, and the coordinate setting part may set the coordinate of the specific position by further using the angle information.

As described above, additional consideration of the angle information for setting the coordinate of the specific position is effective to set an accurate specific position based on the evacuation route of the tip.

In the soldering device according to the aspect, the input receiving part may further receive angle information about a tip evacuation angle representing an angle defined by a surface of the land and an evacuation route of the tip, and the coordinate setting part may sets the coordinate of the specific position, to a coordinate of a position farther away from the soldering position than an intersection position between an imaginary plane perpendicular to the main surface of the printed circuit board from an outer edge of the land and the evacuation route of the tip calculated form the angle information.

Setting the specific position to an outer position (away from the soldering position) than the intersection position of the imaginary plane and the evacuation route as described above, is further effective to suppress the solder scattering in the evacuation of the soldering iron while avoiding an unnecessarily prolonged tact time. The outline of the actual solder layer is empirically known to exist on an inside (on the land) of the imaginary plane. Therefore, the setting of the specific position to a position farther away from the soldering position than the intersection position as described above can ensure suppression of the solder scattering in the evacuation of the soldering iron even in consideration of a shape variation of the solder layer.

In the soldering device according to the aspect, the input receiving part may further receive shape information about a shape of the tip, and the coordinate setting part may set the coordinate of the specific position by further using the shape information.

The setting of the specific position in further consideration of the shape of the tip leads to reliable suppression of the solder scattering in the evacuation of the solder iron even in use of any of various soldering irons with tips having different shapes.

In the soldering device according to the embodiment, the controller may control a speed relevant to the evacuation of the tip to the evacuation speed until a lapse of a predetermined time required for the tip to reach at least the specific position from the soldering position.

As described above, the solder scattering in the evacuation of the soldering iron is also suppressible, even by controlling of the speed relevant to the evacuation of the tip at the low speed (evacuation speed) until the lapse of the predetermined time.

In the soldering device according to the aspect, the input receiving part may further receive feed amount information about an amount of solder to be fed in joining the workpiece to the land, and the coordinate setting part may set the coordinate of the specific position by further using the feed amount information.

The setting of the coordinate of the specific position by using the feed amount information of solder in the above-described manner is further effective to suppress the solder scattering in the evacuation of the soldering iron while avoiding an unnecessarily prolonged tact time. In other words, use of the feed amount of solder achieves estimation of an accurate outline of the solder layer in consideration of the land width. Consequently, adoption of the above-described configuration leads to successful setting of the coordinate of the specific position that is further effective to suppress the solder scattering.

What is claimed is:

1. A soldering device for joining a workpiece to a land provided on a main surface of a printed circuit board, comprising:
a soldering iron having a tip which is heatable;
a driver configured to move the soldering iron;
an input receiver configured to receive an input of size information about a size of the workpiece;
a controller configured to control the driver, wherein
the controller is configured to:
set, based on the size information, a coordinate of a specific position at a predetermined distance from a soldering position where the tip performs soldering; and
set, to a predetermined speed, a speed of the tip in evacuation at a distant position which is farther away from the soldering position than the specific position, and set, to a speed slower than the predetermined speed, an evacuation speed of the tip in evacuation from the soldering position to the specific position.

2. The soldering device according to claim 1, wherein
the input receiver receives width information about a land width of the land as the size information.

3. The soldering device according to claim 2, wherein
the controller sets the coordinate of the specific position on an outer side in an evacuation direction of the tip than a semicircular imaginary region defined by the land width having a center of the semicircular imaginary region at a center of the land width.

4. The soldering device according to claim 3, wherein
the controller sets the coordinate of the specific position in the semicircular imaginary region having a radius of between ½ times and 1 times the land width.

5. The soldering device according to claim 3, wherein
the input receiver further receives angle information about a tip evacuation angle representing an angle defined by a surface of the land and an evacuation route of the tip, and
the controller sets the coordinate of the specific position by further using the angle information.

6. The soldering device according to claim 2, wherein
the input receiver further receives angle information about a tip evacuation angle representing an angle defined by a surface of the land and an evacuation route of the tip, and
the controller sets the coordinate of the specific position, to a coordinate of a position farther away from the soldering position than an intersection position between an imaginary plane perpendicular to the main surface of the printed circuit board extending from an outer edge of the land and the evacuation route of the tip calculated from the angle information.

7. The soldering device according to claim 1, wherein
the input receiver further receives shape information about a shape of the tip, and
the controller sets the coordinate of the specific position by further using the shape information.

8. The soldering device according to claim 1, wherein
the controller controls a speed relevant to the evacuation of the tip to the evacuation speed until a lapse of a predetermined time required for the tip to reach at least the specific position from the soldering position.

9. The soldering device according to claim 1, wherein
the input receiver further receives feed amount information about an amount of solder to be fed in joining the workpiece to the land, and
the controller sets the coordinate of the specific position by further using the feed amount information.
